(19) United States
(12) Patent Application Publication
(10) Pub. No.: US 2020/0385580 A1
(43) Pub. Date: Dec. 10, 2020

(54) CURABLE SILICONE COMPOSITION AND OPTICAL SEMICONDUCTOR DEVICE

(71) Applicant: DOW TORAY CO., LTD., Shinagawa-ku, Tokyo (JP)

(72) Inventors: Tomohiro IIMURA, Ichihara-Shi, Chiba (JP); Kazuhiro NISHIJIMA, Ichihara-Shi, Chiba (JP); Sawako INAGAKI, Ichihara-Shi, Chiba (JP); Haruhiko FURUKAWA, Ichihara-Shi, Chiba (JP)

(21) Appl. No.: 16/634,815

(22) PCT Filed: Jul. 26, 2018
(86) PCT No.: PCT/JP2018/028079

§ 371 Date: Jan. 28, 2020

(30) Foreign Application Priority Data
Jul. 31, 2017 (JP) 2017-148550

(51) Int. Cl. C08L 83/12; H01L 33/50; H01L 33/56

(52) U.S. Cl. CPC C08L 83/12; H01L 33/56; H01L 33/502

(57) ABSTRACT

A curable silicone composition comprises: (A) an organopolysiloxane having at least two alkenyl groups in a molecule; (B) an organopolysiloxane having at least two silicon atom-bonded hydrogen atoms in a molecule and free of a polyether structure; (C) a polyether-modified silicone having a siloxane dendron structure and a polyether structure; and (D) a hydrosilylation reaction catalyst. The curable silicone composition can be used to form an optical semiconductor device having minimal contamination of a case during manufacturing of the optical semiconductor device, good efficiency of light extraction from a light emitting element, and minimal color unevenness or chromaticity deviation. The optical semiconductor device is notable in that a light emitting element is sealed or covered by a cured material of the composition, in addition to having minimal contamination of a case, good efficiency of light extraction, and minimal chromaticity deviation.

### TECHNICAL FIELD

The present invention relates to a curable silicone composition, along with an optical semiconductor device produced using the composition.

### BACKGROUND ART

In optical semiconductor devices such as light emitting diodes (LEDs), it is known to seal or cover a light emitting element with a curable silicone composition containing a phosphor in order to convert the wavelength of light emitted from the light emitting element and thus to obtain light of a desired wavelength (see Patent Documents 1 and 2).

However, blending a phosphor into a curable silicone composition is problematic in that the phosphor precipitates and separates during storage, or the phosphor precipitates and separates due to a drop in viscosity of the composition while the composition is heated and cured, resulting in insufficient efficiency of light extraction from the light emitting element or the occurrence of color unevenness or chromaticity deviation in the obtained optical semiconductor device. Furthermore, because a curable silicone composition containing a phenyl group has low affinity with the case (frame material) of an optical semiconductor device, some optical semiconductor devices are also problematic in that part of the curable silicone composition crawls on the case surface and contaminates the case when the optical semiconductor device is produced.

### PRIOR ART DOCUMENTS

### Patent Documents

Patent Document 1: JP 2002-314142 A

Patent Document 2: JP 2004-359756 A

### SUMMARY OF THE INVENTION

### Problems to be Solved by the Invention

An object of the present invention is to provide a curable silicone composition which enables the formation of an optical semiconductor device having minimal contamination of a case during production of the optical semiconductor device, good efficiency of light extraction from a light emitting element, and minimal color unevenness or chromaticity deviation. Another object of the present invention is to provide an optical semiconductor device that has minimal contamination of a case, good efficiency of light extraction, and minimal color unevenness or chromaticity deviation.

### Means for Solving the Problems

The curable silicone composition of the present invention comprises:

(A) an organopolysiloxane having at least two alkenyl groups in a molecule;
(B) an organopolysiloxane having at least two silicon atom-bonded hydrogen groups in a molecule, in an amount such that the silicon atom-bonded hydrogen atoms in this component are 0.1 to 10.0 mols per 1 mol of alkenyl groups in component (A);
(C) a polyether-modified silicone represented by the general formula (1):

RₓL¹_{y}Q_{z}SiO_{(4-x-y-z)/2} (1)

wherein:
R is a monovalent hydrocarbon group with 1 to 12 carbons and free of an aliphatic unsaturated bond, or a hydrogen atom;
L¹ is a silyl alkyl group having a siloxane dendron structure represented by the general formula (2) when i=1:

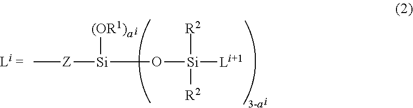

wherein:
R¹ is an alkyl group with 1 to 12 carbons;
R² is a monovalent hydrocarbon group with 1 to 12 carbons and free of an aliphatic unsaturated bond;
Z is an alkylene group with 2 to 12 carbons;
“i” in Lⁱ represents a hierarchy of the silyl alkyl group represented by Lⁱ and is an integer of 1 to “c” when a number of hierarchies, which is a number of repetitions of the silyl alkyl group, is “c”, where the number of hierarchies “c” is an integer of 1 to 10;
Lⁱ⁺¹ is the silyl alkyl group when “i” is less than “c” and is a methyl group or a phenyl group when i=c; and
aⁱ is a number of 0 to 3;
Q is a polyether group bonded to a silicon atom via an alkylene group with 2 to 12 carbons and represented by the formula:

—(OCₘH₂ₘ)ₙOR³

wherein “m” is an integer of 2 to 4; “n” is an integer of 2 or greater; and R³ is a hydrogen atom, an alkyl group, or an acyl group;
and
“x”, “y”, and “z” are numbers satisfying 1.0≤x≤2.5, 0.001≤y≤1.5, and 0.001≤z≤1.5, respectively; and
(D) a hydrosilylation reaction catalyst, in an amount to accelerate curing of the composition,
wherein a content of component (C) is 0.01 to 5 mass % of a total amount of components (A) to (D).

In various embodiments, component (A) is preferably (A₁) a branched or resinous organopolysiloxane having at least two alkenyl groups in a molecule, or a mixture of component (A₁) and (A₂) a linear organopolysiloxane having at least two alkenyl groups in a molecule; component (A₁) is preferably an organopolysiloxane represented by the average unit formula:

(R⁴₃SiO_{1/2})ₐ(R⁴₂SiO_{2/2})_{b}(R⁴SiO_{3/2})_{c}

wherein R⁴s are the same or different alkyl groups with 1 to 12 carbons, alkenyl groups with 2 to 12 carbons, aryl groups with 6 to 12 carbons, or aralkyl groups with 7 to 12 carbons; and “a”, “b”, and “c” are numbers satisfying 0.01≤a≤0.5, 0≤b≤0.7, 0.1≤c≤0.9, and a+b+c=1, respectively; and
a content of component (A₂) is preferably at most 50 mass % of a total amount of components (A) to (D).

Furthermore, in various embodiments, component (B) is preferably (B₁) a linear organopolysiloxane having at least two silicon atom-bonded hydrogen atoms in a molecule, (B₂) a branched or resinous organopolysiloxane having at least two silicon atom-bonded hydrogen atoms in a molecule, or a mixture of components (B₁) and (B₂); component (B₁) is preferably an organopolysiloxane represented by the general formula:

R⁵₃SiO(R⁵₂SiO)ᵣSiR⁵₃

wherein R⁵s are the same or different hydrogen atoms, alkyl groups with 1 to 12 carbons, aryl groups with 6 to 12 carbons, or aralkyl groups with 7 to 12 carbons; and “r” is an integer of 0 to 100; and
component (B₂) is preferably an organopolysiloxane represented by the average unit formula:

(R⁵₃SiO_{1/2})_{d}(R⁵₂SiO_{2/2})ₑ(R⁵SiO_{3/2})_{f}

wherein R⁵s are the same or different hydrogen atoms, alkyl groups with 1 to 12 carbons, aryl groups with 6 to 12 carbons, or aralkyl groups with 7 to 12 carbons; and “d”, “e”, and “f” are numbers that satisfy 0.1≤d≤0.7, 0≤e≤0.7, 0.1≤f<0.9, and d+e+f=1, respectively. Note that in the mixture of components (B₁) and (B₂), a mass ratio of component (B₁) to component (B₂) is preferably 0.5:9.5 to 9.5:0.5.

In various embodiments, in component (C), L¹ is preferably a silyl alkyl group having a siloxane dendron structure represented by the general formula (2-1):

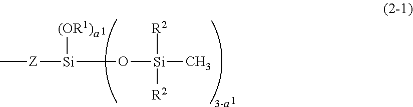

wherein R¹, R², and Z are the same groups as described above, and a¹ is a number of 0 to 3,
or a silyl alkyl group having a siloxane dendron structure represented by the general formula (2-2):

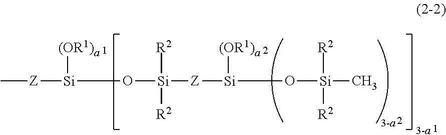

wherein R¹, R², and Z are the same groups as described above, and a¹ and a² are each independently a number of 0 to 3.

In various embodiments, the composition may further comprise: (E) a hydrosilylation reaction inhibitor, in an amount of 0.01 to 3 parts by mass per 100 parts by mass of a total amount of components (A) to (D).

In various embodiments, the composition may further comprise: (F) an adhesion promoter, in an amount of 0.01 to 10 parts by mass per 100 parts by mass of a total amount of components (A) to (D).

In various embodiments, the composition may further comprise: (G) a phosphor, in an amount of 0.1 to 250 parts by mass per 100 parts by mass of a total amount of components (A) to (D).

The optical semiconductor device of the present invention is characterized in that a light emitting element is sealed or covered by a cured product of the curable silicone composition described above.

### Effects of the Invention

The curable silicone composition of the present invention is characterized by enabling the formation of an optical semiconductor device which has minimal contamination of a case during production of the optical semiconductor device, good efficiency of light extraction from a light emitting element, and minimal color unevenness or chromaticity deviation. Furthermore, the optical semiconductor device of the present invention is characterized by minimal contamination of a case, good efficiency of light extraction, and minimal color unevenness or chromaticity deviation.

### BRIEF DESCRIPTION OF THE DRAWINGS

FIG. 1 is a cross sectional view of an LED which is one example of an optical semiconductor device of the present invention.

### MODE FOR CARRYING OUT THE INVENTION

The curable silicone composition of the present invention is described below in detail. Component (A) is an organopolysiloxane serving as a main component of the present composition and having at least two alkenyl groups in a molecule. Exemplary alkenyl groups in component (A) include alkenyl groups with 2 to 12 carbons, such as vinyl groups, allyl groups, butenyl groups, pentenyl groups, hexenyl groups, heptenyl groups, octenyl groups, nonenyl groups, decenyl groups, undecenyl groups, and dodecenyl groups, among which vinyl groups are preferable. Furthermore, exemplary silicon atom-bonded groups other than alkenyl groups in component (A) include: alkyl groups with 1 to 12 carbons, such as methyl groups, ethyl groups, propyl groups, butyl groups, pentyl groups, hexyl groups, heptyl groups, octyl groups, nonyl groups, decyl groups, undecyl groups, and dodecyl groups; aryl groups with 6 to 12 carbons, such as phenyl groups, tolyl groups, xylyl groups, and naphthyl groups; and aralkyl groups with 7 to 12 carbons, such as benzyl groups, phenethyl groups, naphthyl ethyl groups, and naphthyl propyl groups; among which methyl groups and phenyl groups are preferable. Furthermore, a small amount of hydroxyl groups or alkoxy groups such as methoxy groups and ethoxy groups, may be bonded to silicon atoms in component (A) within a range so as not to impair the object of the present invention.

Exemplary molecular structures of component (A) include a linear structure, a partially branched linear structure, a branched structure, and a resinous structure, with component (A) capable of being a mixture having two or more types of these molecular structures. In particular, component (A) is preferably (A₁) a branched or resinous organopolysiloxane having at least two alkenyl groups in a molecule, or a mixture of component (A₁) and (A₂) a linear organopolysiloxane having at least two alkenyl groups in a molecule.

Component (A₁) is a branched or resinous organopolysiloxane having at least two alkenyl groups in a molecule, and preferably an organopolysiloxane represented by the average unit formula:

(R⁴₃SiO_{1/2})ₐ(R⁴₂SiO_{2/2})_{b}(R⁴SiO_{3/2})_{c}.

In the formula, R⁴s are the same or different alkyl groups with 1 to 12 carbons, alkenyl groups with 2 to 12 carbons, aryl groups with 6 to 12 carbons, or aralkyl groups with 7 to 12 carbons, with examples thereof being the same as described above. Note that in a molecule, at least two R⁴s are alkenyl groups. Moreover, for good efficiency of light extraction from a light emitting element, R⁴ in the siloxane unit represented by the formula: R⁴SiO_{3/2} is preferably an aryl group with 6 to 12 carbons, particularly preferably a phenyl group.

Furthermore, in the formula, “a”, “b”, and “c” are numbers that satisfy 0.01≤a≤0.5, 0≤b≤0.7, 0.1≤c<0.9, and a+b+c=1, respectively, preferably numbers that satisfy 0.05≤a≤0.45, 0≤b≤0.5, 0.4≤c<0.85, and a+b+c=1, respectively, and more preferably numbers that satisfy 0.05≤a≤0.4, 0≤b≤0.4, 0.45≤c<0.8, and a+b+c=1, respectively. This is because the gas permeability of a cured product decreases when “a” is greater than or equal to the lower limit of the range described above, while the cured product is less susceptible to stickiness when “a” is less than or equal to the upper limit of the range described above. Furthermore, this is because the hardness of the cured product is good and reliability is improved when “b” is less than or equal to the upper limit of the range described above. Furthermore, this is because the refractive index of the cured product is good when “c” is greater than or equal to the lower limit of the range described above, while the mechanical characteristics of the cured product are improved when “c” is less than or equal to the upper limit of the range described above.

Component (A₁) is represented by the average unit formula described above, but may also have silicon atom-bonded alkoxy groups such as methoxy groups and ethoxy groups, or silicon atom-bonded hydroxyl groups within a range so as not to impair the object of the present invention.

Furthermore, component (A) may be a mixture of component (A₁) and (A₂) a linear organopolysiloxane having at least two alkenyl groups in a molecule.

Component (A₂) is a linear organopolysiloxane having at least two alkenyl groups in a molecule, with examples of the alkenyl groups being the same as the groups described above, among which vinyl groups are preferable. Silicon atoms to which the alkenyl groups are bonded in component (A₂) are not limited, with examples thereof include silicon atoms at the molecular chain end and/or silicon atoms in the molecular chain. Furthermore, exemplary silicon atom-bonded groups other than alkenyl groups in component (A₂) include alkyl groups with 1 to 12 carbons, aryl groups with 6 to 12 carbons, and aralkyl groups with 7 to 12 carbons, as mentioned above, among which methyl groups and phenyl groups are preferable. Furthermore, a small amount of hydroxyl groups or alkoxy groups such as methoxy groups and ethoxy groups, may be bonded to silicon atoms in component (A₂) within a range so as not to impair the object of the present invention.

Examples of component (A₂) include the following organopolysiloxanes. Note that in the formulas, Me, Vi, and Ph respectively represent a methyl group, a vinyl group, and a phenyl group; “p” is an integer of 1 to 1000; and “q” is an integer of 1 to 500; and p≥q and p+q≤1000.

Me₂ViSiO(MePhSiO)ₚSiMe₂Vi

Me₂ViSiO(Me₂SiO)ₚ(Ph₂SiO)_{q}SiMe₂Vi

Ph₂ViSiO(Me₂SiO)ₚSiPh₂Vi

MePhViSiO(MePhSiO)ₚSiMePhVi

Me₂ViSiO(MePhSiO)ₚ(Ph₂SiO)_{q}SiMe₂Vi

MePhViSiO(MePhSiO)ₚ(Ph₂SiO)_{q}SiMePhVi

Ph₂ViSiO(MePhSiO)ₚSiPh₂Vi

Ph₂ViSiO(MePhSiO)ₚ(Ph₂SiO)_{q}SiPh₂Vi

In the present composition, a content of component (A₂) is preferably at most 50 mass %, more preferably at most 30 mass %, of a total amount of components (A) to (D). This is because the mechanical characteristics of a cured product are good when the content of component (A₂) is less than or equal to the upper limit of the range described above. Furthermore, the content of component (A₂) is preferably at least 5 mass % of the total amount of components (A) to (D). This is because the flexibility of the cured product is improved when the content of component (A₂) is greater than or equal to the lower limit of the range described above.

Component (B) is a crosslinking agent of the present composition and is an organopolysiloxane having at least two silicon atom-bonded hydrogen atoms in a molecule. Exemplary silicon atom-bonded groups other than hydrogen atoms in component (B) include: alkyl groups with 1 to 12 carbons, such as methyl groups, ethyl groups, propyl groups, butyl groups, pentyl groups, hexyl groups, heptyl groups, octyl groups, nonyl groups, decyl groups, undecyl groups, and dodecyl groups; aryl groups with 6 to 12 carbons, such as phenyl groups, tolyl groups, xylyl groups, and naphthyl groups; and aralkyl groups with 7 to 12 carbons, such as benzyl groups, phenethyl groups, naphthyl ethyl groups, and naphthyl propyl groups; among which methyl groups and phenyl groups are preferable. Furthermore, a small amount of hydroxyl groups or alkoxy groups such as methoxy groups and ethoxy groups, may be bonded to silicon atoms in component (B) within a range so as not to impair the object of the present invention.

Exemplary molecular structures of component (B) include a linear structure, a partially branched linear structure, a branched structure, and a resinous structure, wherein component (B) may be a mixture having two or more types of these molecular structures. In particular, component (B) is preferably (B₁) a linear organopolysiloxane having at least two silicon atom-bonded hydrogen atoms in a molecule, (B₂) a branched or resinous organopolysiloxane having at least two silicon atom-bonded hydrogen atoms in a molecule, or a mixture of components (B₁) and (B₂).

Component (B₁) is a linear organopolysiloxane having at least two silicon atom-bonded hydrogen atoms in a molecule, and is preferably an organopolysiloxane represented by the general formula:

R⁵₃SiO(R⁵₂SiO)ᵣSiR⁵₃.

In the formula, R⁵s are the same or different hydrogen atoms, alkyl groups with 1 to 12 carbons, aryl groups with 6 to 12 carbons, or aralkyl groups with 7 to 12 carbons, with examples thereof being the same as the groups described above. Note that in a molecule, at least two R⁵s are hydrogen atoms. Moreover, for good efficiency of light extraction from a light emitting element, at least one R⁵ is preferably an aryl group with 6 to 12 carbons, particularly preferably a phenyl group.

Furthermore, in the formula, “r” is an integer in the range of 0 to 100, preferably an integer in the range of 0 to 30, and particularly preferably an integer in the range of 0 to 10 for excellent handling and processability of the present composition.

Exemplary such component (B₁) include the following organopolysiloxanes. Note that in the formulas, Me and Ph respectively represent a methyl group and a phenyl group; “r′ ” is an integer of 1 to 100; and “r” “ is an integer of 1 to 100; where r′+r” is an integer less than or equal to 100.

HMe₂SiO(Ph₂SiO)_{r′}SiMe₂H

HMePhSiO(Ph₂SiO)_{r′}SiMePhH

MePhSiO(Ph₂SiO)_{r′}(MePh₂SiO)_{r″}SiMePhH

HMePhSiO(Ph₂SiO)_{r′}(Me₂SiO)_{r″}SiMePhH

Furthermore, component (B₂) is a branched or resinous organopolysiloxane having at least two silicon atom-bonded hydrogen atoms in a molecule, preferably an organopolysiloxane represented by the average unit formula:

(R⁵₃SiO_{1/2})_{d}(R⁵₂SiO_{2/2})ₑ(R⁵SiO_{3/2})_{f}.

In the formula, R⁵s are the same or different hydrogen atoms, alkyl groups with 1 to 12 carbons, aryl groups with 6 to 12 carbons, or aralkyl groups with 7 to 12 carbons, with examples thereof being the same as the groups described above. Note that in a molecule, at least two R⁵s are hydrogen atoms. In addition, for good efficiency of light extraction from a light emitting element, R⁵ in a siloxane unit represented by the formula R5SiO₃/₂ is preferably an aryl group with 6 to 12 carbons, particularly preferably a phenyl group.

Furthermore, in the formula, “d”, “e”, and “f” are numbers satisfying 0.1≤d≤0.7, 0≤e≤0.7 0.1≤f<0.9, and d+e+f=1, respectively, preferably numbers satisfying 0.2≤d≤0.7, 0≤e≤0.5, 0.25≤f<0.7, and d+e+f=1, respectively. This is because the gas permeability of a cured product decreases when “d” is greater than or equal to the lower limit of the range described above, while the cured product has moderate hardness when “d” is less than or equal to the upper limit of the range described above. Furthermore, this is because the cured product has moderate hardness and the reliability of an optical semiconductor device produced using the present composition is improved when “e” is less than or equal to the upper limit of the range described above. Furthermore, this is because the refractive index of the cured product increases when “f” is greater than or equal to the lower limit of the range described above, while the mechanical strength of the cured product is enhanced when “f” is less than or equal to the upper limit of the range described above.

Examples of such component (B₂) include the following organopolysiloxanes. Note that in the formulas, Me and Ph respectively represent a methyl group and a phenyl group; while “d′”, “d′”, “e′”, and “f” are numbers satisfying 0.01≤d′+d″≤0.7, 0<e′≤0.7, 0.1≤f<0.9, and d′+d″+e′+f=1, respectively.

(HMe₂SiO_{1/2})_{d′}(PhSiO_{3/2})_{f}

(HMePhSiO_{1/2})_{d′}(PhSiO_{3/2})_{f}

(HMePhSiO_{1/2})_{d′}(HMe₂SiO_{1/2})_{d″}(P hSiO_{3/2})_{f}

(HMe₂SiO_{1/2})_{d′}(Ph₂SiO_{2/2})_{e′}(PhSiO_{3/2})_{f}

(HMePhSiO_{1/2})_{d′}(Ph₂SiO_{2/2})_{e′}(PhSiO_{3/2})_{f}

(HMePhSiO_{1/2})_{d′}(HMe₂SiO_{1/2})_{d″}(Ph₂SiO_{2/2})ₑ(PhSiO_{3/2})_{f}

Component (B₁), component (B₂), or a mixture of components (B₁) and (B₂) can be used as component (B). When a mixture of components (B₁) and (B₂) is used, the mixing ratio thereof is not particularly limited, however, the ratio of the mass of component (B₁) to the mass of component (B₂) preferably falls within the range of 0.5:9.5 to 9.5:0.5.

In the present composition, a content of component (B) is an amount such that the silicon atom-bonded hydrogen atoms in this component are within the range of 0.1 to 10 mols, preferably within the range of 0.1 to 5 mols or within the range of 0.5 to 2 mols, per 1 mol of alkenyl groups in component (A). This is because the composition is sufficiently cured when the content of component (B) is greater than or equal to the lower limit of the range described above, while improving the heat resistance of a cure product; consequently, the reliability of an optical semiconductor device produced using the present composition is improved when the content is less than or equal to the upper limit of the range described above.

Component (C) is a polyether-modified silicone having a silyl alkyl group (-L1) with a siloxane dendron structure and a polyether group (-Q), and represented by the general formula (1):

RₓL¹_{y}Q_{z}SiO_{(4-x-y-z)/2} (1).

This type of component (C) suppresses crawling of the present composition on the surface of the case of an optical semiconductor device when producing the optical semiconductor device, thus contributing to the flattening of the surface of a cured product obtained by curing the present composition, and further improves the dispersibility of a phosphor when blended with the phosphor, thus contributing to the suppression of color unevenness and color shifting in the optical semiconductor device.

In the formula, R is a monovalent hydrocarbon group with 1 to 12 carbons and free of an aliphatic unsaturated bond, or a hydrogen atom. Examples of the monovalent hydrocarbon group of R include: alkyl groups with 1 to 12 carbons, such as methyl groups, ethyl groups, propyl groups, butyl groups, pentyl groups, hexyl groups, heptyl groups, octyl groups, decyl groups, and undecyl groups; aryl groups with 6 to 12 carbons, such as phenyl groups, tolyl groups, xylyl groups, and naphthyl groups; and aralkyl groups with 7 to 12 carbons, such as benzyl groups, phenethyl groups, and phenyl propyl groups; among which 90 mol to 100% of R are preferably methyl groups, ethyl groups, or phenyl groups.

Furthermore, in the formula, the group represented by L¹ is a silyl alkyl group having a siloxane dendron structure, and is a silyl alkyl group having a siloxane dendron structure represented by the general formula (2) when i=1:

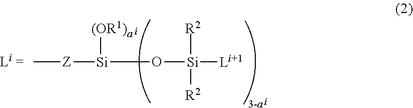

A silyl alkyl group having this siloxane dendron structure includes a structure in which the carbosiloxane units extend in a dendrimer form, and exhibits performance superior to that of linear or simple branched polysiloxane units.

In the formula, R₁ is an alkyl group with 1 to 12 carbons, with examples thereof including the same as the groups described above.

In addition, in the formula, R² is a monovalent hydrocarbon group with 1 to 12 carbons and free of an aliphatic unsaturated bond, with examples thereof including alkyl groups with 1 to 12 carbons, aryl groups with 6 to 12 carbons, and aralkyl groups with 7 to 12 carbons as those described above.

Furthermore, in the formula, Z is an alkylene group with 2 to 12 carbons, with examples thereof including ethylene groups, propylene groups, methylpropylene groups, butylene groups, and pentylene groups.

Furthermore, “i” in Lⁱ represents the hierarchy of the silyl alkyl group represented by Lⁱ and is an integer of 1 to “c” when the number of hierarchies, which is the number of repetitions of the silyl alkyl group, is “c”, where the number of hierarchies “c” is an integer of 1 to 10, and Lⁱ⁺¹ is the silyl alkyl group when “i” is less than “c”, and is a methyl group or a phenyl group when i=c.

Note that the number of hierarchies “c” is preferably an integer of 1 to 3 and is more preferably 1 or 2 from an industrial standpoint. In each number of hierarchies, the group represented by Lⁱ is expressed as follows. In the formula, R² and Z are the same groups as described above.

When the number of hierarchies is c=1, L¹ is represented by the general formula (2-1):

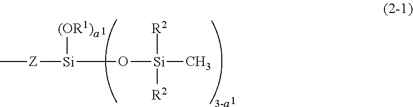

Furthermore, when the number of hierarchies is c=2, L¹ is represented by the general formula (2-2):

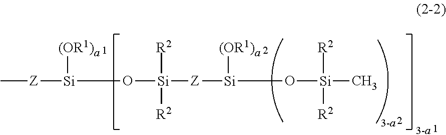

When the number of hierarchies is c=3, L¹ is represented by the general formula (2-3):

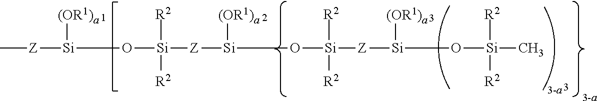

In addition, aⁱ in the formula is a number within the range of 0 to 3, and in the structures represented by the formulas (2-1) to (2-3) in which the number of hierarchies is 1 to 3, a¹, a², and a³ are each independently a number within the range of 0 to 3. These aⁱ are preferably numbers within the range of 0 to 1, and aⁱ is particularly preferably 0.

Furthermore, in the formula, Q is a polyether group bonded to a silicon atom via an alkylene group with 2 to 12 carbons and represented by the formula:

—(OCₘH₂ₘ)ₙOR³.

In the formula, “m” is an integer of 2 to 4 and preferably 2 or 3.

Furthermore, in the formula, “n” is an integer not less than 2, and preferably an integer in the range of 2 to 50, an integer in the range of 4 to 50, or an integer in the range of 8 to 30.

In addition, in the formula, R³ is a hydrogen atom, an alkyl group, or an acyl group. Examples of the alkyl group of R³ include methyl groups, ethyl groups, and propyl groups. In addition, examples of the acyl group of R³ include acetyl groups.

Furthermore, in the formula, “a”, “b”, and “c” are numbers satisfying 1.0≤a≤2.5, 0.001≤b≤1.5, and 0.001≤c≤1.5.

This type of component (C) can be prepared by hydrosilylation reacting a compound having a siloxane dendron structure capped at one molecular terminal by alkenyl group and a polyether group capped at one molecular terminal with an alkenyl group with respect to an organopolysiloxane having silicon atom-bonded hydrogen atoms.

In the present composition, a content of component (C) is within the range of 0.01 to 5 mass %, preferably within the range of 0.01 to 3 mass %, within the range of 0.01 to 2 mass %, within the range of 0.01 to 1 mass %, or within the range of 0.01 to 0.5 mass %, of a total amount of components (A) to (D). This is because if the content of component (C) is greater than or equal to the lower limit of the range described above, crawling of the present composition on the case when producing an optical semiconductor device can be suppressed and the dispersibility of a phosphor improved when the present composition is blended with the phosphor; further, the surface of a cured product obtained by curing the present composition can be easily flattened, while the transparency of the cured product is good if the content is less than or equal to the upper limit of the range described above.

Component (D) is a hydrosilylation reaction catalyst for accelerating curing of the present composition, with examples thereof including platinum-based catalysts, rhodium-based catalysts, and palladium-based catalysts. In particular, component (D) is preferably a platinum-based catalyst, since it can noticeably accelerate curing of the present composition. Exemplary platinum-based catalysts include finely powdered platinum, chloroplatinic acid, an alcohol solution of chloroplatinic acid, platinum-alkenyl siloxane complexes, platinum-olefin complexes, and platinum-carbonyl complexes, among which platinum-alkenyl siloxane complexes are preferable.

Furthermore, in the present composition, a content of component (D) is an amount effective for accelerating curing of the present composition. Specifically, for the capability of sufficiently accelerating the curing reaction of the present composition, the content of component (D) is preferably an amount in which catalytic metals in component (D) relative to the present composition are within the range of 0.01 to 500 ppm, more preferably within the range of 0.01 to 100 ppm, and particularly preferably within the range of 0.01 to 50 ppm, in terms of mass units.

The present composition may comprise: (E) a hydrosilylation reaction inhibitor to control the pot life thereof. Examples of such component (E) include: alkyne alcohols, such as 2-methyl-3-butyn-2-ol, 3,5-dimethyl-1-hexyn-3-ol, and 2-phenyl-3-butyn-2-ol; enyne compounds, such as 3-methyl-3-penten-1-yne, and 3,5-dimethyl-3-hexen-1-yne; 1,3,5,7-tetramethyl-1,3,5,7-tetravinyl cyclotetrasiloxane, 1,3,5,7-tetramethyl-1,3,5,7-tetrahexenyl cyclotetrasiloxane, and benzotriazole.

In the present composition, while a content of component (E) is not limited, it is preferably within the range of 0.01 to 3 parts by mass per 100 parts by mass of a total mass of components (A) to (D) described above.

Furthermore, the present composition may comprise: (F) an adhesion promoter in order to improve the adhesion of a cured product to a substrate with which the cured product is brought into contact during curing. Component (F) is preferably an organosilicon compound having at least one alkoxy group or epoxy group-containing monovalent organic group bonded to a silicon atom in a molecule. Examples of this alkoxy group include a methoxy group, an ethoxy group, a propoxy group, a butoxy group, and a methoxyethoxy group, with a methoxy group particularly preferable. Furthermore, exemplary epoxy group-containing monovalent organic groups include: glycidoxyalkyl groups, such as 3-glycidoxypropyl groups, and 4-glycidoxybutyl groups; epoxycyclohexyl alkyl groups, such as 2-(3,4-epoxycyclohexyl)ethyl groups, and 3-(3,4-epoxycyclohexyl)propyl groups; and oxiranylalkyl groups, such as 4-oxiranylbutyl groups, and 8-oxiranyloctyl groups, among which glycidoxyalkyl groups are particularly preferable.

Exemplary groups other than alkoxy groups or epoxy group-containing monovalent organic groups that are bonded to a silicon atom of the organosilicon compound include: substituted or unsubstituted monovalent hydrocarbon groups, such as alkyl groups, alkenyl groups, aryl groups, aralkyl groups, and halogenated alkyl groups; acryl group-containing monovalent organic groups, such as 3-methacryloxypropyl groups; and hydrogen atoms. The organosilicon compound preferably has silicon atom-bonded alkenyl groups or silicon atom-bonded hydrogen atoms. Moreover, because favorable adhesion can be imparted to various substrates, this organosilicon compound preferably has at least one epoxy group-containing monovalent organic group in a molecule. Examples of such an organosilicon compound include an organosilane compound, an organosiloxane oligomer, and an alkyl silicate. Exemplary molecular structures of this organosiloxane oligomer or alkyl silicate include a linear structure, a partially branched linear structure, a branched structure, a cyclic structure, and a network structure, among which a linear structure, a branched structure, and a network structure are particularly preferable. Specifically, exemplary such organosilicon compounds include: silane compounds, such as 3-glycidoxypropyl trimethoxysilane, 2-(3,4-epoxycyclohexyl)ethyl trimethoxysilane, and 3-methacryloxypropyl trimethoxysilane; siloxane compounds having at least one silicon atom-bonded alkenyl group or silicon atom-bonded hydrogen atom and at least one silicon atom-bonded alkoxy group in a molecule; a mixture of a silane compound or siloxane compound having at least one silicon atom-bonded alkoxy group and a siloxane compound having at least one silicon atom-bonded hydroxyl group and at least one silicon atom-bonded alkenyl group in a molecule; methylpolysilicate; ethylpolysilicate; epoxy group-containing ethylpolysilicate; and an organopolysiloxane containing an epoxy group and an alkenyl group and represented by the average composition formula:

R⁶ₕR⁷ᵢSiO_{(4-h-i)/2}.

In the formula for the organopolysiloxane containing an epoxy group and an alkenyl group, R⁶ represents an epoxy group-containing monovalent organic group, with examples thereof being the same as the groups described above, among which glycidoxyalkyl groups are preferable. Moreover, R⁷ represents an alkyl group with 1 to 12 carbons, alkenyl group with 2 to 12 carbons, aryl group with 6 to 12 carbons, or an aralkyl group with 7 to 12 carbons, with examples thereof being the same as the groups described above. Note that 1 mol % or more of all R⁷ are alkenyl groups, with 3 mol % or more or 10 mol % or more preferably being alkenyl groups. From the perspective of compatibility with the present composition, at least 3 mol % or at least 10 mol % of all R⁷ are preferably phenyl groups. “h” is a number within the range of 0.05 to 1.8, preferably a number within the range of 0.05 to 0.7, or a number within the range of 0.1 to 0.6. Moreover, “i” is a number within the range of 0.10 to 1.80, preferably a number within the range of 0.20 to 1.80. Such an organopolysiloxane containing an epoxy group and an alkenyl group can be prepared by cohydrolyzing an epoxy group-containing alkoxysilane and an alkenyl group-containing alkoxysilane. Note that the epoxy group-containing organopolysiloxane may contain a small amount of alkoxy groups derived from the raw material thereof.

While a content of component (F) in the present composition is not limited, for good adhesion to a substrate in contact therewith during curing, the content is preferably within the range of 0.01 to 10 parts by mass per 100 parts by mass of a total amount of components (A) to (D) described above.

Furthermore, the present composition may comprise: (G) a phosphor for converting the wavelength of light emitted from a light emitting element formed by being sealed or coated by the cured product of the present composition to obtain light of a desired wavelength. Examples of such component (G) include yellow, red, green, and blue light phosphors which are widely used in light emitting diodes (LEDs) and comprise oxide phosphors, oxynitride phosphors, nitride phosphors, sulfide phosphors, oxysulfide phosphors, and the like. Exemplary oxide phosphors include: yttrium, aluminum, and garnet-type YAG green to yellow light phosphors containing cerium ions; terbium, aluminum, and garnet-type TAG yellow light phosphors containing cerium ions; and silicate green to yellow light phosphors containing cerium or europium ions. Exemplary oxynitride phosphors include silicon, aluminum, oxygen, and nitrogen type SiAION red to green light phosphors containing europium ions. Exemplary nitride phosphors include calcium, strontium, aluminum, silicon, and nitrogen type CASN red light phosphors containing europium ions. Exemplary sulfide phosphors include ZnS green light phosphors containing copper ions or aluminum ions. Exemplary oxysulfide phosphors include Y₂O₂S red light phosphors containing europium ions. The phosphors may be used independently or in combinations of two or more.

A content of component (G) in the present composition is within the range of 0.1 to 250 parts by mass, preferably within the range of 1 to 100 parts by mass, within the range of 1 to 50 parts by mass, or within the range of 1 to 30 parts by mass, per 100 parts by mass of a total amount of components (A) to (D).

Furthermore, the present composition may comprise, as other optional components: an inorganic filler, such as silica, glass, alumina, and zinc oxide; an organic resin fine powder, such as a polymethacrylate resin; a heat resistant agent; a dye; a pigment; a flame retarder; a solvent; and the like, so long as the object of the present invention is not impaired.

Although curing of the present composition proceeds at room temperature or by heating, heating is preferable in order to quickly cure the composition. The heating temperature for this is preferably within the range of 50 to 200° C.

Next, the optical semiconductor device of the present invention will be explained in detail. The optical semiconductor device of the present invention is formed by sealing an optical semiconductor element using the cured product of the curable silicone composition described above. Exemplary optical semiconductor devices of the present invention include light emitting diodes (LEDs), photocouplers, and CCDs. Exemplary optical semiconductor elements include light emitting diode (LED) chips and solid state image sensing devices.

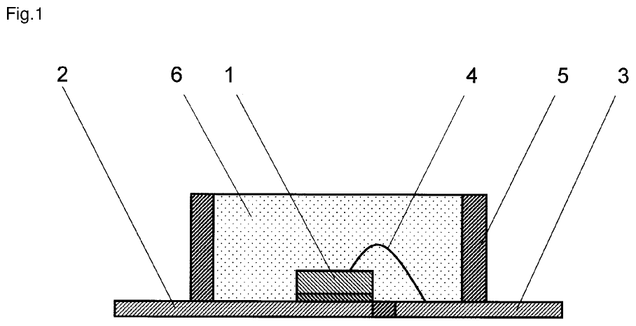

FIG. 1 illustrates a cross sectional view of a single surface mounted type LED as one example of an optical semiconductor device of the present invention. In the LED illustrated in FIG. 1, a light emitting element (LED chip) 1 is die bonded on a lead frame 2, while the light emitting element (LED chip) 1 and a lead frame 3 are wire bonded together by a bonding wire 4. A frame material 5 is provided around the light emitting element (LED chip) 1 and the light emitting element (LED chip) 1 inside the frame material 5 is sealed by a cured product 6 of the curable silicone composition of the present invention.

Exemplary methods for producing the surface mounted type LED illustrated in FIG. 1 include a method of die bonding the light emitting element (LED chip) 1 on the lead frame 2, wire bonding the light emitting element (LED chip) 1 and the lead frame 3 together via the metal bonding wire 4, and then filling the curable silicone composition of the present invention inside the frame material 5 provided around the light emitting element (LED chip) 1 before heating to 50 to 200° C.

### EXAMPLES

The curable silicone composition and optical semiconductor device of the present invention will be described in detail using examples. Note that the viscosity (mPa·s) is the value measured at 25° C. using a rotational viscometer conforming to JIS K7117-1, while the kinetic viscosity (mm²/s) is the value measured at 25° C. with an Ubbelohde viscometer conforming to JIS Z8803. Furthermore, in the formula, Me, Vi, Ph, and Ep represent a methyl group, a vinyl group, a phenyl group, and a 3-glycidoxypropyl group, respectively.

### Synthesis Example 1

First, 102.52 g of an organopolysiloxane represented by the formula:

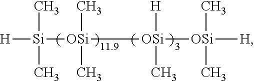

352.53 g of an allyloxy polyalkylene oxide represented by the formula:

CH₂═CH—CH₂—O—(CH₂CH₂O)₄(CH₂CH(CH₃)O)₁₈H,

150.0 g of isopropyl alcohol, and 0.1875 g of an isopropyl alcohol solution of a platinum-1,3-divinyl-1,1,3,3-tetramethyldisiloxane complex (platinum content=4 mass %) were charged into a four-neck flask equipped with a stirrer, a reflux condenser, and a thermometer and then heated at 80° C. for 2 hours. Next, 82.7 g of vinyl tris(trimethylsiloxy)silane was charged and heated for 2 hours. Further, 7.2 g of 1-hexene was charged and heated for 2 more hours. After the disappearance of silicon-hydrogen bonds in the reaction mixture was confirmed in the infrared absorption spectrum, the low-boiling-point components were removed to prepare a polyether-modified silicone having a kinematic viscosity of 420 mm²/s and represented by the formula:

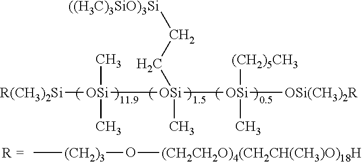

### Synthesis Example 2

First, 23.46 g of an organopolysiloxane represented by the formula:

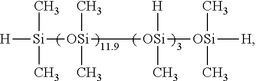

57.62 g of an allyloxy polyalkylene oxide represented by the formula:

CH₂═CH—CH₂—O—(CH₂CH₂O)₄(CH₂CH(CH₃)O)₁₈H,

50.0 g of toluene, and 0.05 g of an isopropyl alcohol solution of a platinum-1,3-divinyl-1,1,3,3-tetramethyldisiloxane complex (platinum content=4 mass %) were charged into a four-neck flask equipped with a stirrer, a reflux condenser, and a thermometer and then heated at 80° C. for 2 hours. Next, 18.92 g of vinyl tris(trimethylsiloxy)silane was charged and heated for 2 hours. After the disappearance of silicon-hydrogen bonds in the reaction mixture was confirmed in the infrared absorption spectrum, the low-boiling-point components were removed to prepare a polyether-modified silicone having a kinematic viscosity of 520 mm²/s and represented by the formula:

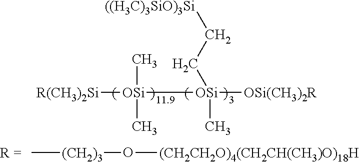

### Synthesis Example 3

First, 14.86 g of an organopolysiloxane represented by the average unit formula:

(HMe₂SiO_{1/2})_{0.6}(PhSiO_{3/2})_{0.4},

71.43 g of an allyloxy polyalkylene oxide represented by the formula:

CH═CHCH₂O(C₂H₄O)₄(C₃H₆O)₁₈H,

30.0 g of toluene, and 0.05 g of an isopropyl alcohol solution of a platinum-1,3-divinyl-1,1,3,3-tetramethyldisiloxane complex (platinum content=4 mass %) were charged into a four-neck flask equipped with a stirrer, a reflux condenser, and a thermometer and then heated at 80° C. for 2 hours. Next, 26.07 g of vinyl tris(trimethylsiloxy)silane was charged and heated for 2 hours. After the disappearance of silicon-hydrogen bonds in the reaction mixture was confirmed in the infrared absorption spectrum, the low-boiling-point components were removed to prepare a polyether-modified silicone having a kinematic viscosity of 650 mm²/s and represented by the average unit formula:

(XMe₂SiO_{1/2})_{0.6}(PhSiO_{3/2})_{0.4}

wherein 50 mol % of X is a polyether residue represented by the formula:

—C₃H₆O(C₂H₄O)₄(C₃H₆O)₁₈H,

and the remaining 50 mol % is a tris(trimethylsiloxy)silylethyl group represented by the formula:

—C₂H₄Si[OSi(CH₃)₃].

### Reference Example 4

Into a four neck flask equipped with a stirrer, a reflux condenser, and a thermometer was input 82.2 g of 1,3-divinyl-1,1,3,3-tetramethyldisiloxane, 143 g of water, 0.38 g of a trifluoromethane sulfonic acid, and 500 g of toluene, into which 524.7 g of a phenyltrimethoxysilane was added dropwise over 1 hour while stirring. Once dripping was complete, the mixture was heated and refluxed for 1 hour. Thereafter, the mixture was cooled, the lower layer was separated, and the toluene solution layer was washed with water three times. 314 g of methylglycidoxypropyldimethoxysilane, 130 g of water, and 0.50 g of potassium hydroxide were input in the water washed toluene solution layer, after which the mixture was heated and refluxed for 1 hour. Subsequently, methanol was distilled off and excess water was removed by azeotropic dehydration. After heating and refluxing for 4 hours, the toluene solution was cooled, neutralized with 0.55 g of acetic acid, and then washed with water three times. After the water was removed, toluene was distilled off under reduced pressure, and an adhesion promoter having a viscosity of 8,500 mPa·s and represented by the average unit formula:

(Me₂ViSiO_{1/2})_{0.18}(PhSiO_{3/2})_{0.53}(EpMeSiO_{2/2})_{0.29}

was prepared.

### Examples 1 to 4 and Comparative Example 1

Using the following components, curable silicone compositions of the examples and comparative example, which have the compositions shown in Table 1, were prepared. Note that in Table 1, “SiH/Vi” represents the molar ratio of silicon atom-bonded hydrogen atoms in component (B) to vinyl groups in component (A).

The following components were used as component (A).

(a-1): an organopolysiloxane resin represented by the average unit formula:

(Me₂ViSiO_{1/2})_{0.25}(PhSiO_{3/2})_{0.75}.

(a-2): a methylphenylpolysiloxane having a viscosity of 3,000 mPa·s and capped at both molecular terminals with dimethylvinylsiloxy groups.
(a-3): a dimethylpolysiloxane having a viscosity of 32 mPa·s and capped at both molecular terminals with diphenylvinylsiloxy groups.

The following components were used as component (B).

(b-1): an organotrisiloxane represented by the formula:

HMe₂SiOPh₂SiOSiMe₂H.

(b-2): an organopolysiloxane resin represented by the average unit formula:

(Me₂HSiO_{1/2})_{0.6}(PhSiO_{3/2})_{0.4}.

The following components were used as component (C).

(c-1): the polyether-modified silicone prepared in Reference Example 1.
(c-2): the polyether-modified silicone prepared in Reference Example 2.
(c-3): the polyether-modified silicone prepared in Reference Example 3.

The following component was used as component (D).

(d-1): a 1,3-divinyl-1,1,3,3-tetramethyldisiloxane solution of a platinum-1,3-divinyl-1,1,3,3-tetramethyldisiloxane complex (platinum content =5 mass %).
Note that in Table 1, the content of component (E) is expressed as the content (ppm), in mass units, of platinum metal relative to the curable silicone composition.

The following components were used as component (E).

(e-1): 1-ethynylcyclohexan-1-ol
(e-2): 1,3,5,7-tetramethyl-1,3,5,7-tetravinylcyclotetrasiloxane

The following component was used as component (F).

(f-1): the adhesion promoter prepared in Reference Example 4.

The following components were used as component (G).

(g-1): green phosphor (product name: GAL530, from INTEMATIX)
(g-2): red phosphor (product name: ER6535, from INTEMATIX)

### Transmittance of Cured Product

The temperature of 0.5 g of the curable silicone composition excluding component (G) was raised from room temperature to 150° C. over 30 minutes using a mold (50 mm×50 mm×2 mm), then heated at 150° C. for 1 hour, thereby preparing a cured product having a thickness of 2 mm. Transmittance of the cured product was measured using a ultraviolet absorption measurement device from Shimadzu Seisakusho.

### Light Extraction Efficiency and Color Deviation of the Optical Semiconductor Device

The curable silicone composition containing component (G) was injected into an optical semiconductor device as illustrated in FIG. 1, then heated at 150° C. for 2 hours to be cured. The light extraction efficiency and color deviation of the obtained optical semiconductor device were determined by total radiant flux measurement using an integrating sphere.

### Crawling on the Optical Semiconductor Device

The curable silicone composition containing component (G) was injected into an optical semiconductor device, the case of which was made of PCT, as illustrated in FIG. 1, and heated at 150° C. for 2 hours to be cured. The surfaces of the obtained optical semiconductor devices were observed using an optical microscope and evaluated such that optical semiconductor devices without crawling out of their cases were marked by “◯”, while optical semiconductor devices with crawling on their case surfaces were marked by “x”.

TABLE 1

| | | | Segment | | | | |
|---|---|---|---|---|---|---|---|
| | | | | | | | Comparative |
| | | | Present Invention | | | | Example |
| | | | Example | Example | Example | Example | Comparative |
| Items | | | 1 | 2 | 3 | 4 | Example 1 |
| Composition of curable | (A) | (a-1) | 68.2 | 68.2 | 68.2 | 68.2 | 68.2 |
| silicon composition | | (a-2) | 7.5 | 7.5 | 7.5 | 7.5 | 7.5 |
| (parts by mass) | | (a-3) | — | — | — | 0.1 | — |
| | (B) | (b-1) | 20.4 | 20.4 | 20.4 | 20.4 | 20.4 |
| | | (b-2) | 1.0 | 1.0 | 1.0 | 1.0 | 1.0 |
| | (C) | (c-1) | 0.2 | — | — | — | — |
| | | (c-2) | — | 0.2 | — | 0.1 | — |
| | | (c-3) | — | — | 0.2 | — | — |
| | (D) | (d-1) | 2 ppm | 2 ppm | 2 ppm | 2 ppm | 2 ppm |
| | (E) | (e-1) | 0.02 | 0.02 | 0.02 | 0.02 | 0.02 |
| | | (e-2) | 0.2 | 0.2 | 0.2 | 0.2 | 0.2 |
| | (F) | (f-1) | 2.5 | 2.5 | 2.5 | 2.5 | 2.5 |
| | (G) | (g-1) | 20.7 | 20.7 | 20.7 | 20.7 | 20.7 |
| | | (g-2) | 1.5 | 1.5 | 1.5 | 1.5 | 1.5 |

| | | | | | |
|---|---|---|---|---|---|
| SiH/Vi | 1.0 | 1.0 | 1.0 | 1.0 | 1.0 |
| Transmittance (%) | 94.0 | 95.0 | 95.0 | 95.0 | 95.0 |
| Light extraction efficiency | 12200 | 11600 | 12200 | 11600 | 11300 |
| Standard deviation of X | 0.001533 | 0.001273 | 0.001151 | 0.001640 | 0.002581 |
| Standard deviation of Y | 0.002296 | 0.002348 | 0.003220 | 0.002055 | 0.006392 |
| Crawling | ∘ | ∘ | ∘ | ∘ | x |

### INDUSTRIAL APPLICABILITY

The curable silicone composition of the present invention enables the formation of an optical semiconductor device having good efficiency of light extraction from a light emitting element in addition to having minimal color unevenness or chromaticity deviation, making it suitable as a sealing agent or a coating agent for a light emitting element in an optical semiconductor device, such as a light emitting diode (LED). Moreover, the curable silicone composition of the present invention maintains good transparency and is therefore also suitable as an optical member for which transparency is required.

### REFERENCE NUMERALS

1: Light emitting element
2: Lead frame
3: Lead frame
4: Bonding wire
5: Frame material
6: Cured product of curable silicone composition

1. A curable silicone composition comprising:
(A) an organopolysiloxane having at least two alkenyl groups in a molecule;
(B) an organopolysiloxane having at least two silicon atom-bonded hydrogen groups in a molecule and free of a polyether structure, in an amount such that the silicon atom-bonded hydrogen atoms in this component are 0.1 to 10.0 mols per 1 mol of alkenyl groups in component (A);
(C) a polyether-modified silicone represented by the general formula (1):
RₓL¹_{y}Q_{z}SiO_{(4-x-y-z)/2} (1)
wherein:
R is a monovalent hydrocarbon group with 1 to 12 carbons and free of an aliphatic unsaturated bond, or a hydrogen atom;
L¹ is a silyl alkyl group having a siloxane dendron structure represented by the general formula (2) when i=1: 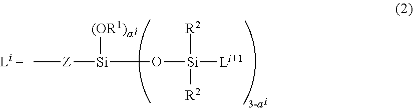
wherein:
R¹ is an alkyl group with 1 to 12 carbons;
R² is a monovalent hydrocarbon group with 1 to 12 carbons and free of an aliphatic unsaturated bond;
Z is an alkylene group with 2 to 12 carbons;
“i” in Lⁱ represents a hierarchy of the silyl alkyl group represented by Lⁱ and is an integer of 1 to “c” when a number of hierarchies, which is a number of repetitions of the silyl alkyl group, is “c”, where the number of hierarchies “c” is an integer of 1 to 10;
Lⁱ⁺¹ is the silyl alkyl group when “i” is less than “c” and is a methyl group or a phenyl group when i=c; and
aⁱ is a number of 0 to 3;
Q is a polyether group bonded to a silicon atom via an alkylene group with 2 to 12 carbons and represented by the formula:
—(OCₘH₂ₘ)ₙOR³
wherein “m” is an integer of 2 to 4; “n” is an integer of 2 or greater; and R³ is a hydrogen atom, an alkyl group, or an acyl group; and
“x”, “y”, and “z” are numbers satisfying 1.0≤x≤2.5, 0.001≤y≤1.5, and 0.001≤z≤1.5, respectively; and
(D) a hydrosilylation reaction catalyst, in an amount to accelerate curing of the composition;
wherein a content of component (C) is 0.01 to 5 mass % of a total amount of components (A) to (D).

2. The curable silicone composition according to claim 1, wherein component (A) is (A₁) a branched or resinous organopolysiloxane having at least two alkenyl groups in a molecule, or a mixture of component (A₁) and (A₂) a linear organopolysiloxane having at least two alkenyl groups in a molecule.

3. The curable silicone composition according to claim 2, wherein component (A₁) is an organopolysiloxane represented by the average unit formula:
(R⁴₃SiO_{1/2})ₐ(R⁴₂SiO_{2/2})_{b}(R⁴SiO_{3/2})_{c}
wherein R⁴s are the same or different alkyl groups with 1 to 12 carbons, alkenyl groups with 2 to 12 carbons, aryl groups with 6 to 12 carbons, or aralkyl groups with 7 to 12 carbons; and “a”, “b”, and “c” are numbers satisfying 0.01≤a≤0.5, 0≤b≤0.7, 0.1≤c≤0.9, and a+b+c=1, respectively.

4. The curable silicone composition according to claim 2, wherein component (A₂) is present and a content of component (A₂) is at most 50 mass % of a total amount of components (A) to (D).

5. The curable silicone composition according to claim 1, wherein component (B) is (B₁) a linear organopolysiloxane having at least two silicon atom-bonded hydrogen atoms in a molecule, (B₂) a branched or resinous organopolysiloxane having at least two silicon atom-bonded hydrogen atoms in a molecule, or a mixture of components (B₁) and (B₂).

6. The curable silicone composition according to claim 5, wherein component (B₁) is present and is an organopolysiloxane represented by the general formula:
R⁵₃SiO(R⁵₂SiO)ᵣSiR⁵₃
wherein R⁵s are the same or different hydrogen atoms, alkyl groups with 1 to 12 carbons, aryl groups with 6 to 12 carbons, or aralkyl groups with 7 to 12 carbons; and “r” is an integer of 0 to 100.

7. The curable silicone composition according to claim 5, wherein component (B₂) is present and is an organopolysiloxane represented by the average unit formula:
(R⁵₃SiO_{1/2})_{d}(R⁵₂SiO_{2/2})ₑ(R⁵SiO_{3/2})_{f}
wherein R⁵s are the same or different hydrogen atoms, alkyl groups with 1 to 12 carbons, aryl groups with 6 to 12 carbons, or aralkyl groups with 7 to 12 carbons; and “d”, “e”, and “f” are numbers satisfying 0.1<d<0.7, 0<e<0.7, 0.1<f<0.9, and d+e+f=1, respectively.

8. The curable silicone composition according to claim 5, wherein the mixture is present and, in the mixture of components (B₁) and (B₂), the mass ratio of component (B₁) to component (B₂) is 0.5:9.5 to 9.5:0.5.

9. The curable silicone composition according to claim 1, wherein in component (C), L¹ is a silyl alkyl group having a siloxane dendron structure represented by the general formula (2-1): 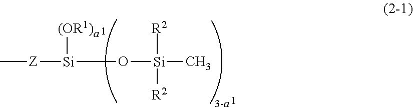
wherein R¹, R², and Z are the same groups as described above, and a¹ is a number of 0 to 3,
or a silyl alkyl group having a siloxane dendron structure represented by the general formula (2-2): 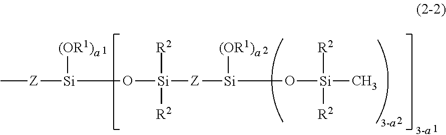
wherein R¹, R², and Z are the same groups as described above, and a¹ and a² are each independently a number of 0 to 3.

10. The curable silicone composition according to claim 1, further comprising:
(E) a hydrosilylation reaction inhibitor, in an amount of 0.01 to 3 parts by mass per 100 parts by mass of a total amount of components (A) to (D).

11. The curable silicone composition according to claim 1, further comprising:
(F) an adhesion promotor, in an amount of 0.01 to 10 parts by mass per 100 parts by mass of a total amount of components (A) to (D).

12. The curable silicone composition according to claim 1, further comprising:
(G) a phosphor, in an amount of 0.1 to 250 parts by mass per 100 parts by mass of a total amount of components (A) to (D).

13. An optical semiconductor device comprising a light emitting element, wherein a-the light emitting element is sealed or covered by a cured product of the curable silicone composition according to claim 1.
